(19) United States
(12) Patent Application Publication
(10) Pub. No.: US 2026/0304699 A1
(43) Pub. Date: Oct. 1, 2026

(54) THREE-DIMENSIONAL VAPOR CHAMBER

(71) Applicant: WAH HONG INDUSTRIAL CORP., KAOHSIUNG (TW)

(72) Inventors: Ko-Chun CHEN, KAOHSIUNG (TW); Chih-Jen HUANG, KAOHSIUNG (TW)

(21) Appl. No.: 19/276,021

(22) Filed: Jul. 22, 2025

(30) Foreign Application Priority Data
Mar. 26, 2025 (TW) 114202994

(51) Int. Cl. H05K 7/20

(52) U.S. Cl. CPC H05K 7/20336

(57) ABSTRACT

A three-dimensional vapor chamber includes a vapor chamber module and a vertical flat cooling module. The vapor chamber module includes an upper shell structure, and the upper shell structure includes an upper shell body and an upper shell capillary structure formed in the upper shell body. The vertical flat cooling module is fixed on the vapor chamber module and in fluid communication with the vapor chamber. In addition, the vertical flat cooling module includes a vertical flat cooling shell fixed on the upper shell body, and a vertical flat capillary structure formed in the vertical flat cooling shell and connected to the upper shell capillary structure.

### RELATED APPLICATIONS

This application claims priority to Taiwan Application Serial Number 114202994, filed Mar. 26, 2025, the disclosures of which are incorporated herein by reference in their entireties.

### TECHNICAL FIELD

The present disclosure relates to a three-dimensional vapor chamber. More particularly, the present disclosure relates to a three-dimensional vapor chamber having a vertical flat cooling module.

### BACKGROUND

With the advancement of science and technology, the computing power of the electronic devices is increasing day by day, and the temperature control of electronic components such as processors of the electronic devices is becoming more and more important. Especially, when the computing speed of the working chip in the electronic devices such as mobile phones, tablets, and notebook computers, continues to increase, the ambient temperature of the system of the electronic device may also increase, but the system stability may therefore reduce.

In order to solve the foregoing problem, various heat dissipation devices such as the heat pipes and vapor chambers are adopted to dissipate heat generated by the working chip, so that the heat of the working chip may be quickly discharged from the system of the electronic devices such as mobile phones, tablets, laptop computers or any electronic devices with higher source, e.g. server computers, network devices or wireless transmission devices, so as to control the temperature within the system and further maintain the system stability.

The three-dimensional vapor chamber combined the vapor chamber and the heat pipe may be connected to the heat source that needs to dissipate heat, and connected to the heat sink fins or other heat dissipation devices to transfer the heat to the heat sink fins or other heat dissipation devices using the three-dimensional vapor chamber so as to take the heat out of the electronic devices such as mobile phones, tablets, laptops and any electronic devices. In addition, as the heat dissipation requirements of the electronic devices become higher and higher, various heat dissipation devices are gradually designed and developed.

Therefore, there is a need to further improve the heat dissipation efficiency of the three-dimensional vapor chamber so as to improve the working efficiency of the processors and the electronic devices.

### SUMMARY

The summary of the present invention is intended to provide a simplified description of the disclosure to enable readers to have a basic understanding of the disclosure. The summary of the present invention is not a complete overview of the disclosure, and it is not intended to point out the importance of the embodiments/key elements of the present invention or define the scope of the invention.

One objective of the embodiments of the present invention is to provide a three-dimensional vapor chamber to improve the heat dissipation efficiency of the vapor chamber.

To achieve these and other advantages and in accordance with the objective of the embodiments of the present invention, as the embodiment broadly describes herein, the embodiments of the present invention provides a three-dimensional vapor chamber including a vapor chamber module and a vertical flat cooling module. The vapor chamber module includes an upper shell structure, and the upper shell structure includes an upper shell body and an upper shell capillary structure formed in the upper shell body. The vertical flat cooling module is fixed on the vapor chamber module and in fluid communication with the vapor chamber module. In addition, the vertical flat cooling module includes a vertical flat cooling shell fixed on the upper shell body and a vertical flat capillary structure formed in the vertical flat cooling shell and connected to the upper shell capillary structure.

In some embodiments, a thickness of the vertical flat cooling module is greater than 0.5 mm and a width of the vertical flat cooling module is greater than 8 mm.

In some embodiments, a width-to-thickness ratio of the vertical flat cooling module is greater than 10:1.

In some embodiments, the upper shell body includes an upper shell main body and a raised joint portion. The raised joint portion is formed in the upper shell main body, and the vertical flat cooling shell arranged to pass through the raised joint portion.

In some embodiments, the vertical flat cooling shell includes a vertical flat cooling main body and an expansion joint portion. The expansion joint portion is connected to the vertical flat cooling main body and engaged with the raised joint portion of the upper shell body.

In some embodiments, the upper shell capillary structure includes an upper shell main capillary structure and an upper shell raising capillary structure. The upper shell main capillary structure is formed on an interior surface of the upper shell main body and the upper shell raising capillary structure is connected to the upper shell main capillary structure and formed inside the raised joint portion.

In some embodiments, the vertical flat capillary structure includes a vertical flat main capillary structure and a vertical flat expansion capillary structure. The vertical flat main capillary structure is formed on an interior surface of the vertical flat cooling main body, and the vertical flat expansion capillary structure is connected to the vertical flat main capillary structure and formed inside the expansion joint portion.

In some embodiments, an end face of the upper shell raising capillary structure is connected to end faces of the vertical flat expansion capillary structure and the expansion joint portion.

In some embodiments, the vertical flat expansion capillary structure is embedded in the upper shell raising capillary structure.

In some embodiments, the vertical flat expansion capillary structure is engaged between the upper shell raising capillary structure and the expansion joint portion.

In some embodiments, the upper shell raising capillary structure is engaged between the vertical flat expansion capillary structure and the raised joint portion.

In some embodiments, the upper shell body further includes a joint flange connected to the raised joint portion and engaged with the expansion joint portion of the vertical flat cooling shell.

In some embodiments, a part of the vertical flat expansion capillary structure of the vertical flat capillary structure is connected to the upper shell raising capillary structure of the upper shell capillary structure.

In some embodiments, the vapor chamber module further includes a lower shell structure closely connected to the upper shell structure, and the lower shell structure includes a lower shell body and a lower shell capillary structure formed on an interior surface of the lower shell body, and a peripheral area of the upper shell capillary structure is connected to the lower shell capillary structure.

Therefore, according to the structures of the above three-dimensional vapor chambers of the present invention, the three-dimensional vapor chamber may utilize the vertical flat expansion capillary structure of the vertical flat capillary structure to partially or annularly connect to the upper shell raising capillary structure of the upper shell capillary structure to increase the flowing efficiency of the cooling fluid and improve the heat dissipation efficiency of the three-dimensional vapor chamber. In addition, the three-dimensional vapor chambers of the present invention may further utilize the vertical flat cooling modules to increase the surface area of the vertical flat cooling modules, the contact area between the vertical flat cooling modules and the vapor chamber module, and the total heat dissipation area of the three-dimensional vapor chamber so as to significantly improve the heat dissipation efficiency of the three-dimensional vapor chamber and the connection strength between the vertical flat cooling modules and the vapor chamber module with a same surface area of the vapor chamber module. Additionally, the parallel arrangement of the vertical flat cooling modules may further guide the cooling airflow across the outer surface of the three-dimensional vapor chamber so as to further increase the heat dissipation efficiency of the three-dimensional vapor chamber.

### BRIEF DESCRIPTION OF THE DRAWINGS

The disclosure can be more fully understood by reading the following detailed description of the embodiment, with reference made to the accompanying drawings as follows:

FIG. 1 illustrates a schematic perspective view of a three-dimensional vapor chamber according to one embodiment of the present invention;

FIG. 2 illustrates a partial enlarged cross-section view of a three-dimensional vapor chamber according to one embodiment of the present invention;

FIG. 3 illustrates a partial enlarged cross-section view of a three-dimensional vapor chamber according to another embodiment of the present invention;

FIG. 4 illustrates a partial enlarged cross-section view of a three-dimensional vapor chamber according to further another embodiment of the present invention;

FIG. 5 illustrates a partial enlarged cross-section view of a three-dimensional vapor chamber according to still further another embodiment of the present invention;

FIG. 6 illustrates a schematic exploded view of a three-dimensional vapor chamber according to one embodiment of the present invention; and

FIG. 7 illustrates a schematic perspective top view of a three-dimensional vapor chamber according to one embodiment of the present invention.

### DETAILED DESCRIPTION OF THE PREFERRED EMBODIMENT

The following is a detailed description of the embodiments in conjunction with the accompanying drawings, but the provided embodiments are not intended to limit the scope of the disclosure, and the description of the structure and operation is not used to limit the execution sequence thereof. The structure of the recombination of components and the resulting devices with equal functions are all within the scope of this disclosure. In addition, the drawings are for illustration purposes only, and are not drawn according to the original scale. For ease of understanding, the same reference numbers are used in the drawings and the description to refer to the same or like parts.

In addition, the terms used in the entire description and the scope of the patent application, unless otherwise specified, usually have the usual meaning of each term used in this field, in the content disclosed here and in the special content. Some terms used to describe the disclosure are discussed below or elsewhere in this specification to provide additional guidance to those skilled in the art in the disclosure.

In the implementation mode and the scope of the present application, unless the article is specifically limited in the context, “a” and “the” can generally refer to a single or pluralities. In the steps, the numbering is only used to conveniently describe the steps, rather than to limit the sequence and implementation.

Secondly, the words “comprising”, “including”, “having”, “containing” and the like used in the present application are all open language, meaning including but not limited to.

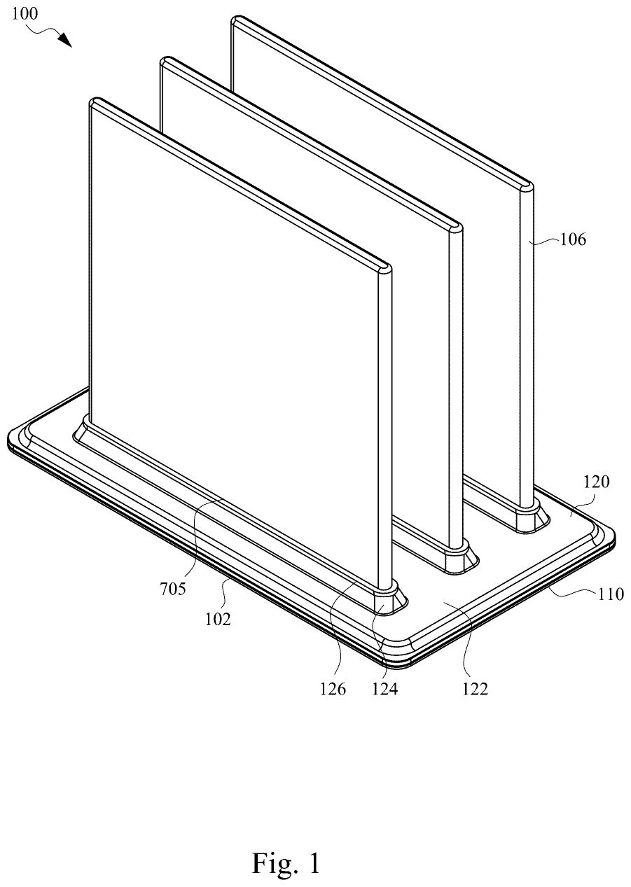

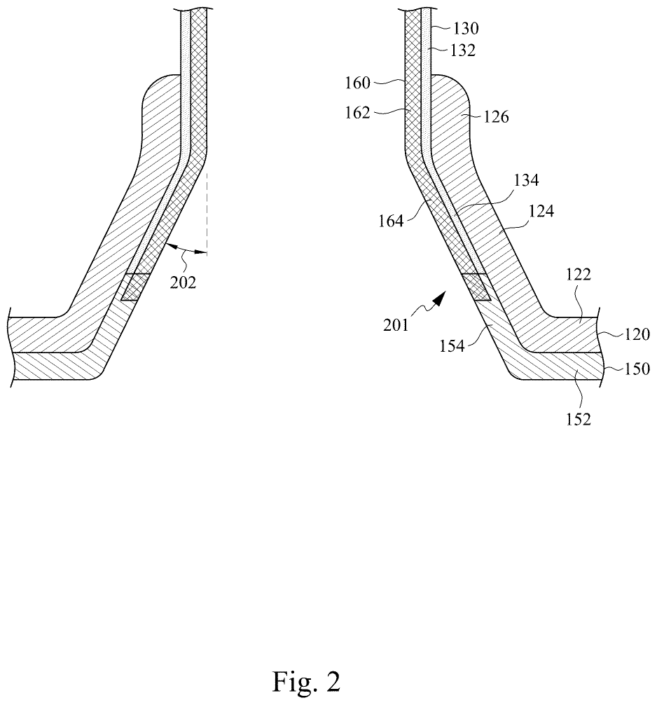

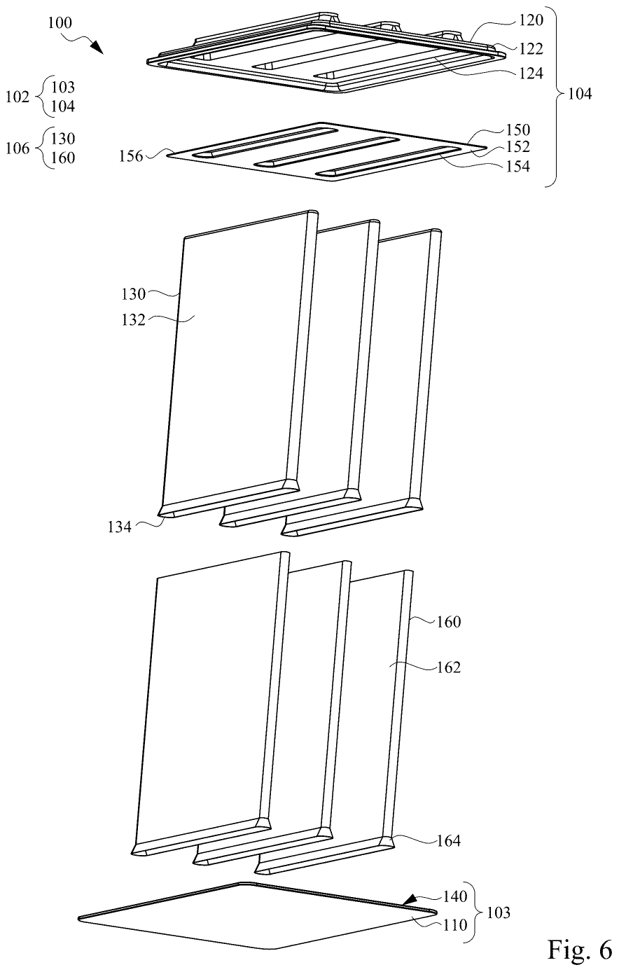

FIGS. 1, 6 and 7 illustrate a schematic perspective view, a schematic exploded view, a schematic top view of a three-dimensional vapor chamber according to one embodiment of the present invention, and FIGS. 2-5 illustrate partial enlarged cross-section views of three-dimensional vapor chambers according to a plurality of embodiments of the present invention.

Referring to FIGS. 1, 6 and 7, the three-dimensional vapor chamber 100 includes a vapor chamber module 102 and a vertical flat cooling module 106. The vapor chamber module 102 includes an upper shell structure 104 and a lower shell structure 103. In addition, the upper shell structure 104 includes an upper shell body 120 and an upper shell capillary structure 150 formed in the upper shell body 120. In addition, the upper shell body 120 and the upper shell capillary structure 150 may be integrally formed, or may be independently formed and assembly together. In some embodiments, the upper shell body 120 can be formed first and then the upper shell capillary structure 150 is formed in the upper shell body 120, for example, through a sintering process or a bonding process, without departing from the spirit and protection scope of the present invention.

In addition, the vertical flat cooling module 106 is fixed on the vapor chamber module 102 and is in fluid communication with the vapor chamber module 102 to allow the cooling fluid flowing between the vapor chamber module 102 and the vertical flat cooling module 106. In addition, the vertical flat cooling module 106 includes a vertical flat cooling shell 130 fixed on the upper shell body 120 and a vertical flat capillary structure 160 formed in the vertical flat cooling shell 130 and connected to the upper shell capillary structure 150. In addition, the vertical flat cooling shell 130 and the vertical flat capillary structure 160 may be integrally formed, or may be independently formed and assembly together. In some embodiments, the vertical flat cooling shell 130 can be formed first and then the vertical flat capillary structure 160 is formed in the vertical flat cooling shell 130, for example, through a sintering process or a bonding process, without departing from the spirit and protection scope of the present invention.

In some embodiments, the lower shell body 110 and the upper shell body 120 are sealed to form a sealed chamber and the cooling fluid is disposed in the sealed chamber to cool a heat source. The vertical flat cooling shell 130 is fixed on the upper shell body 120 and is in fluid communication with the sealed chamber to allow the cooling fluid flowing between the vertical flat cooling shell 130 and the sealed chamber between the lower shell body 110 and the upper shell body 120.

In addition, an upper shell capillary structure 150 is formed on the interior surface of the upper shell body 120, a vertical flat capillary structure 160 is formed in the vertical flat cooling shell 130, and the vertical flat capillary structure 160 is connected to the upper shell capillary structure 150 to increase the flowing velocity and efficiency of the cooling fluid in the three-dimensional vapor chamber 100 so as to improve the heat dissipation efficiency of the three-dimensional vapor chamber 100.

In addition, a lower shell capillary structure 140 is formed on the interior surface of the lower shell body 110 to increase the flowing velocity and efficiency of the cooling fluid in the three-dimensional vapor chamber 100. In some embodiments, the peripheral area 156 of the upper shell capillary structure 150 is preferably connected to the lower shell capillary structure 140 to increase the flowing velocity and efficiency of the cooling fluid.

In some embodiments, the lower shell body 110 and the upper shell body 120 may be sealed together through brazing, soldering, high-frequency welding, laser welding, and resistance welding. In some embodiments, an adhesive may also be used to seal the lower shell body 110 and the upper shell body 120.

In some embodiments, the joint flange 126 of the upper shell body 120 and the vertical flat cooling module 106 can be joined along the annular fixing portion 705 by brazing, soldering, high-frequency welding, laser welding, and resistance welding, or by using an adhesive, without departing from the spirit and protection scope of the present invention.

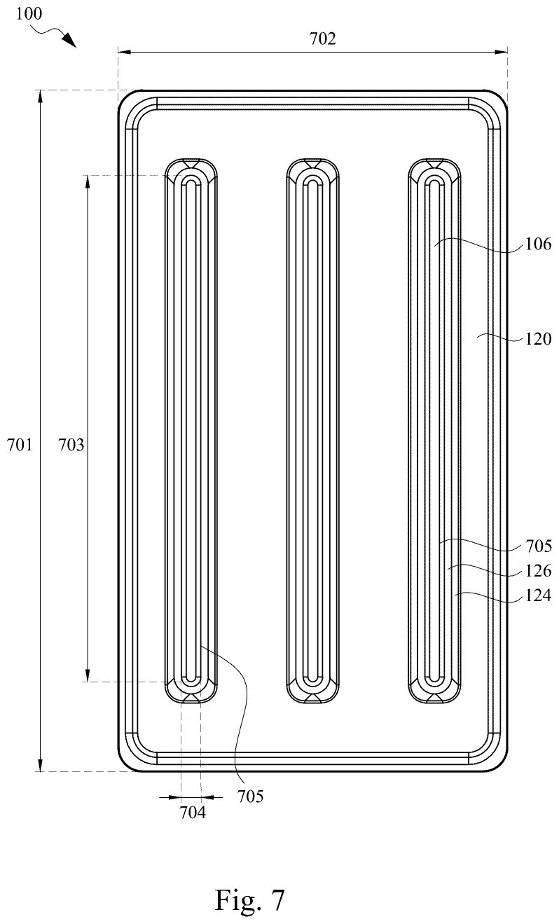

Referring specifically to FIG. 7, as shown in the figure, in some embodiments, a ratio of the width 703 to the thickness 704 of the vertical flat cooling module 106 is greater than about 10:1, and more preferably greater than 20:1. In some embodiments, the width 703 of the vertical flat cooling module 106 is greater than 8 millimeters (mm), and the thickness 704 is greater than 0.5 millimeters (mm).

In some embodiments, the width 703 of the vertical flat cooling module 106 is approximately 104 millimeters (mm), and the thickness 704 is approximately 4 millimeters.

In some embodiments, a ratio of the width 703 of the vertical flat cooling module 106 to the width 701 of the vapor chamber module 102 is approximately greater than 3:10, for example, 6:10, and preferably approximately greater than 10:12. For example, the width 703 of the vertical flat cooling module 106 is approximately 104 millimeters (mm), and the width 701 of the vapor chamber module 102 is approximately 120 millimeters.

In some embodiments, the thickness 704 of the vertical flat cooling module 106 is approximately 4 millimeters, and the thickness 702 of the vapor chamber module 102 is approximately 80 millimeters.

Therefore, when the thickness 702 of the vapor chamber module 102 is 80 millimeters and the width 701 of the vapor chamber module 102 is approximately 120 millimeters, the width 703 of the vertical flat cooling module 106 of the present invention may be set to 104 millimeters, and the thickness 704 may be set to 4 millimeters. The vapor chamber module 102 may be equipped with three or more vertical flat cooling modules 106, and the vertical flat cooling modules 106 is utilized to guide the heat dissipation airflow to more effectively reduce the temperature of the electronic device and the three-dimensional vapor chamber 100, and improve the heat dissipation efficiency thereof.

In some embodiments, the vertical flat cooling module 106 may be formed by flattening a heat pipe, or the vertical flat cooling module 106 may be a flat heat dissipation hollow casing directly formed or machined by conductive metal to fluidly connect to the vapor chamber module 102. In some embodiments, the hollow casing of the vertical flat cooling module 106 may preferably contain a capillary structure, directly formed or machined on the surface of the internal chamber of the hollow casing.

Simultaneously referring to FIG. 2, in some embodiments, the upper shell body 120 includes an upper shell main body 122 and a raised joint portion 124. The raised joint portion 124 is formed on the upper shell main body 122, and the vertical flat cooling shell 130 is arranged to upwardly pass through the raised joint portion 124 from the bottom thereof, that is, the vertical flat cooling shell 130 passes through the raised joint portion 124 from the inner side to the outside thereof, to allow the vertical flat cooling shell 130 in fluid communication with the sealed chamber between the lower shell body 110 and the upper shell body 120.

In some embodiments, the vertical flat cooling shell 130 includes a vertical flat cooling main body 132 and an expansion joint portion 134. The expansion joint portion 134 is connected to the vertical flat cooling main body 132, and the expansion joint portion 134 is engaged with the raised joint portion 124 of the upper shell body 120 to closely connect the vertical flat cooling shell 130 to the upper shell body 120.

In some embodiments, the vertical flat cooling shell 130 and the upper shell body 120 may be sealed together through brazing, soldering, high-frequency welding, laser welding, and resistance welding. In some embodiments, an adhesive may also be used to seal the vertical flat cooling shell 130 and the upper shell body 120.

In some embodiments, the upper shell capillary structure 150 includes an upper shell main capillary structure 152 and an upper shell raising capillary structure 154. The upper shell main capillary structure 152 is formed on the interior surface of the upper shell main body 122. The upper shell raising capillary structure 154 is connected to the upper shell main capillary structure 152 and is formed inside the raised joint portion 124.

In addition, the vertical flat capillary structure 160 includes a vertical flat main capillary structure 162 and a vertical flat expansion capillary structure 164. The vertical flat main capillary structure 162 is formed on the interior surface of the vertical flat cooling main body 132. The vertical flat expansion capillary structure 164 is connected to the vertical flat main capillary structure 162 and formed inside the expansion joint portion 134.

Further referring to FIG. 2, in some embodiments, at the connection position 201, the vertical flat expansion capillary structure 164 and the expansion joint portion 134 are embedded together. That is to say, the end face of the vertical flat expansion capillary structure 164 protrudes from the end face of the expansion joint portion 134 and embedded in the upper shell raising capillary structure 154 to increase the connection strength and the transmission efficiency of the cooling fluid.

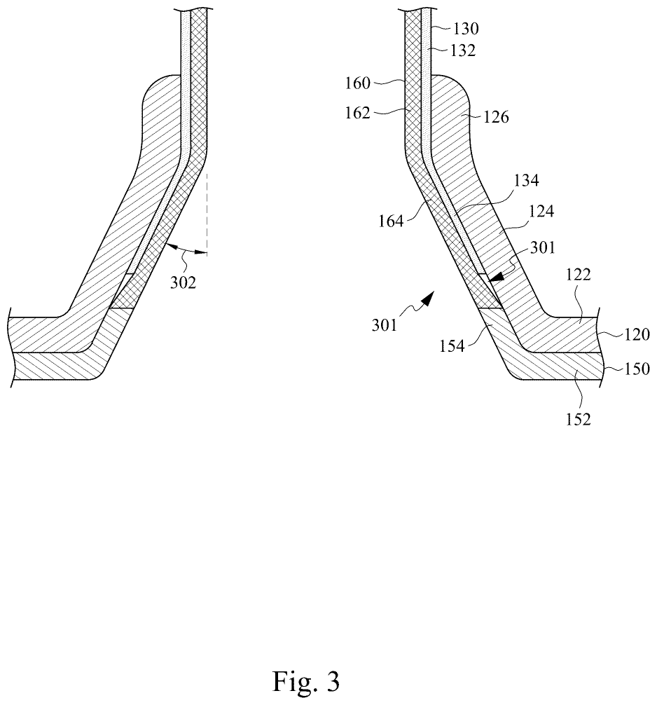

Referring to FIG. 3, in some embodiments, at the connection position 301, the end face of the vertical flat expansion capillary structure 164 is connected to the end face of the upper shell raising capillary structure 154. That is to say, the end face of the vertical flat expansion capillary structure 164 is aligned with the end face of the expansion joint portion 134 to connect the end face of the vertical flat expansion capillary structure 164 and the end face of the upper shell raising capillary structure 154. In addition, a room is formed at the connection position 301 to store the cooling fluid. In some embodiments, the room is sealed by the upper shell raising capillary structure 154 to connect the vertical flat expansion capillary structure 164 to the upper shell raising capillary structure 154 to further increase the transmission efficiency of the cooling fluid.

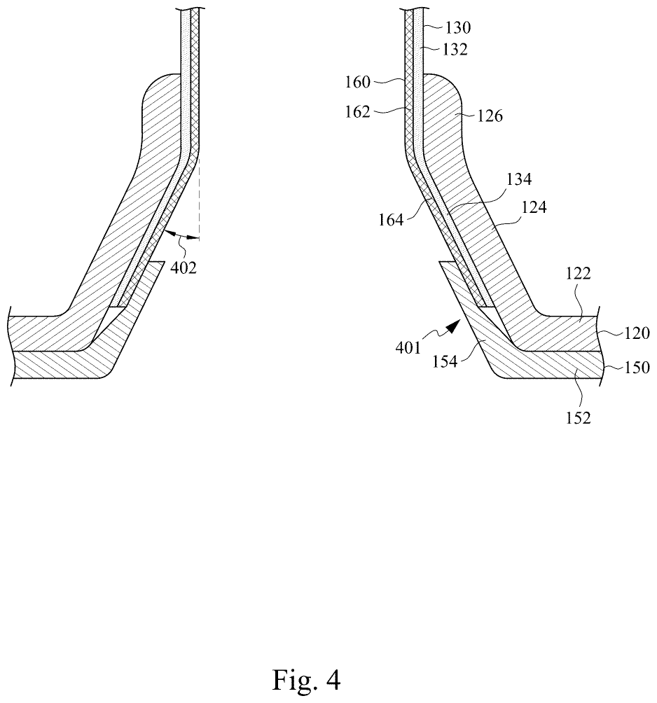

Further referring to FIG. 4, in some embodiments, at the connection position 401, the vertical flat expansion capillary structure 164 is engaged between the upper shell raising capillary structure 154 and the expansion joint portion 134. That is to say, the vertical flat expansion capillary structure 164 is clamped between the upper shell raising capillary structure 154 and the expansion joint portion 134, and the expansion joint portion 134 is engaged inside the raised joint portion 124 to increase the connection area and the connection strength of the capillary structure so as to increase the transmission efficiency of the cooling fluid and the heat dissipation efficiency of the three-dimensional vapor chamber 100.

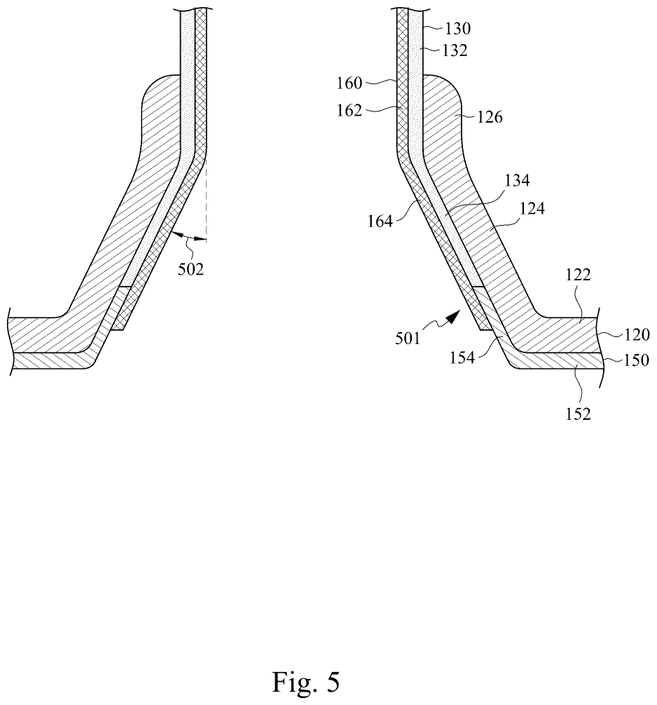

In addition, referring to FIG. 5, in some embodiments, at the connection position 501, the upper shell raising capillary structure 154 is engaged between the vertical flat expansion capillary structure 164 and the raised joint portion 124. That is to say, the upper shell raising capillary structure 154 is clamped between the vertical flat expansion capillary structure 164 and the raised joint portion 124. In addition, the expansion joint portion 134 is engaged inside the raised joint portion 124 to increase the connection area and the connection strength of the capillary structure so as to increase the transmission efficiency of the cooling fluid and the heat dissipation efficiency of the three-dimensional vapor chamber 100.

In some embodiments, referring to FIGS. 2-5, an expansion angle is formed between the vertical flat expansion capillary structure 164 and the vertical flat main capillary structure 162, for example, the expansion angles 202, 302, 402 and 502 as shown in FIGS. 2-5, and is preferably greater than 0.5 degrees and less than 90 degrees, such as 1 degree, 5 degrees, 10 degrees, 15 degrees, 25 degrees, 30 degrees, 45 degrees, 50 degrees, 55 degrees, 60 degrees, 65 degrees, 70 degrees, 75 degrees, 80 degrees, 85 degrees or 89 degrees and so on, without departing from the spirit and protection scope of the present invention.

In some embodiments, it is worth noting that, the upper shell body 120 further includes a joint flange 126 connected to the raised joint portion 124 to engaged with the expansion joint portion 134 of the vertical flat cooling shell 130. In some embodiments, the inner diameter of the joint flange 126 is approximately equal to the outer diameter of the vertical flat cooling main body 132, for example, 2 mm or above, to effectively transmit the cooling fluid and improve the working efficiency.

In addition, in some embodiments, the vertical flat expansion capillary structure 164 of the vertical flat capillary structure 160 is connected to the upper shell raising capillary structure 154 of the upper shell capillary structure 150 all around, for example, connected in an annular shape to increase heat dissipation efficiency.

In some embodiments, the annular perimeter of the vertical flat expansion capillary structure 164 of the vertical flat capillary structure 160 is not completely connected to the upper shell raising capillary structure 154 of the upper shell capillary structure 150. That is to say, only a part of the vertical flat expansion capillary structure 164 of the vertical flat capillary structure 160 is connected to the upper shell raising capillary structure 154 of the upper shell capillary structure 150, and therefore only some positions of the vertical flat expansion capillary structure 164 of the vertical flat capillary structure 160 are connected to the upper shell raising capillary structure 154 of the upper shell capillary structure 150 to conveniently manufacture the three-dimensional vapor chamber 100 and also improve the heat dissipation efficiency of the three-dimensional vapor chamber 100.

In some embodiments, the vertical flat expansion capillary structure 164 and the upper shell raising capillary structure 154 are connected together by a single or multiple point connection, line connection, surface connection, end face connection or overlapping connection, or a full circumference connection, without departing from the spirit and protection scope of the present invention.

In some embodiments, the vertical flat capillary structure 160 and the upper shell capillary structure 150 may include, but are not limited to, porous capillary structure, powder sintered capillary structure, fine groove capillary structure, braided mesh capillary structure, braided strip capillary structure, any material with the capillary phenomena, or a composite capillary structure including any of the above, without departing from the spirit and protection scope of the present invention.

Hence, according to the structures of the above three-dimensional vapor chambers of the present invention, the three-dimensional vapor chamber may utilize the vertical flat expansion capillary structure of the vertical flat capillary structure to partially or annularly connect to the upper shell raising capillary structure of the upper shell capillary structure to increase the flowing efficiency of the cooling fluid and improve the heat dissipation efficiency of the three-dimensional vapor chamber. In addition, the three-dimensional vapor chambers of the present invention may further utilize the vertical flat cooling modules to increase the surface area of the vertical flat cooling modules, the contact area between the vertical flat cooling modules and the vapor chamber module, and the total heat dissipation area of the three-dimensional vapor chamber so as to significantly improve the heat dissipation efficiency of the three-dimensional vapor chamber and the connection strength between the vertical flat cooling modules and the vapor chamber module with a same surface area of the vapor chamber module. Additionally, the parallel arrangement of the vertical flat cooling modules may further guide the cooling airflow across the outer surface of the three-dimensional vapor chamber so as to further increase the heat dissipation efficiency of the three-dimensional vapor chamber.

Although the present disclosure has been disclosed above in terms of implementation, it is not intended to limit the present disclosure. Any person with ordinary knowledge in the field may make various variations and modifications without departing from the spirit and scope of the disclosure. Therefore, the spirit and scope of the appended claims should not be limited to the description of the embodiments contained herein.

What is claimed is:

1. A three-dimensional vapor chamber, comprising:
a vapor chamber module, comprising an upper shell structure, wherein the upper shell structure comprises an upper shell body and an upper shell capillary structure formed in the upper shell body; and
a vertical flat cooling module fixed on the vapor chamber module and in fluid communication with the vapor chamber module, wherein the vertical flat cooling module comprises a vertical flat cooling shell fixed on the upper shell body; and
a vertical flat capillary structure formed in the vertical flat cooling shell and connected to the upper shell capillary structure.

2. The three-dimensional vapor chamber of claim 1, wherein a thickness of the vertical flat cooling module is greater than 0.5 mm and a width of the vertical flat cooling module is greater than 8 mm.

3. The three-dimensional vapor chamber of claim 2, wherein a width-to-thickness ratio of the vertical flat cooling module is greater than 10:1.

4. The three-dimensional vapor chamber of claim 1, wherein the upper shell body comprises:
an upper shell main body; and
a raised joint portion formed in the upper shell main body, and the vertical flat cooling shell arranged to pass through the raised joint portion.

5. The three-dimensional vapor chamber of claim 4, wherein the vertical flat cooling shell comprises:
a vertical flat cooling main body; and
an expansion joint portion connected to the vertical flat cooling main body and engaged with the raised joint portion of the upper shell body.

6. The three-dimensional vapor chamber of claim 5, wherein the upper shell capillary structure comprises:
an upper shell main capillary structure formed on an interior surface of the upper shell main body; and
an upper shell raising capillary structure connected to the upper shell main capillary structure and formed inside the raised joint portion.

7. The three-dimensional vapor chamber of claim 6, wherein the vertical flat capillary structure comprises:
a vertical flat main capillary structure formed on an interior surface of the vertical flat cooling main body; and
a vertical flat expansion capillary structure connected to the vertical flat main capillary structure, and formed inside the expansion joint portion.

8. The three-dimensional vapor chamber of claim 7, wherein an end face of the upper shell raising capillary structure is connected to end faces of the vertical flat expansion capillary structure and the expansion joint portion.

9. The three-dimensional vapor chamber of claim 7, wherein the vertical flat expansion capillary structure is engaged with the upper shell raising capillary structure.

10. The three-dimensional vapor chamber of claim 7, wherein the vertical flat expansion capillary structure is connected between the upper shell raising capillary structure and the expansion joint portion.

11. The three-dimensional vapor chamber of claim 7, wherein the upper shell raising capillary structure is connected between the vertical flat expansion capillary structure and the raised joint portion.

12. The three-dimensional vapor chamber of claim 7, wherein the upper shell body further comprises:
a joint flange connected to the raised joint portion and engaged with the expansion joint portion of the vertical flat cooling shell.

13. The three-dimensional vapor chamber of claim 7, wherein a part of the vertical flat expansion capillary structure of the vertical flat capillary structure is connected to the upper shell raising capillary structure of the upper shell capillary structure.

14. The three-dimensional vapor chamber of claim 1, wherein the vapor chamber module further comprises:
a lower shell structure closely connected to the upper shell structure, wherein the lower shell structure comprises a lower shell body and a lower shell capillary structure formed on an interior surface of the lower shell body, and a peripheral area of the upper shell capillary structure is connected to the lower shell capillary structure.

15. A three-dimensional vapor chamber, comprising:
a vapor chamber module, comprising an upper shell structure, wherein the upper shell structure comprises an upper shell body and an upper shell capillary structure formed in the upper shell body; and
a vertical flat cooling module fixed on the vapor chamber module and in fluid communication with the vapor chamber module,
wherein the vertical flat cooling module comprises a vertical flat cooling shell fixed on the upper shell body; and
a vertical flat capillary structure formed in the vertical flat cooling shell and connected to the upper shell capillary structure,
wherein the vapor chamber module further comprises:
a lower shell structure closely connected to the upper shell structure, wherein the lower shell structure comprises a lower shell body and a lower shell capillary structure formed on an interior surface of the lower shell body, and a peripheral area of the upper shell capillary structure is connected to the lower shell capillary structure, wherein the upper shell body comprises:
an upper shell main body; and
a raised joint portion formed in the upper shell main body, and the vertical flat cooling shell arranged to pass through the raised joint portion wherein the vertical flat cooling shell comprises:
a vertical flat cooling main body; and
an expansion joint portion connected to the vertical flat cooling main body and engaged with the raised joint portion of the upper shell body.

16. The three-dimensional vapor chamber of claim 15, wherein a thickness of the vertical flat cooling module is greater than 0.5 mm and a width of the vertical flat cooling module is greater than 8 mm, and a width-to-thickness ratio of the vertical flat cooling module is greater than 10:1.

17. The three-dimensional vapor chamber of claim 16, wherein the upper shell capillary structure comprises:
an upper shell main capillary structure formed on an interior surface of the upper shell main body; and
an upper shell raising capillary structure connected to the upper shell main capillary structure and formed inside the raised joint portion,
wherein the vertical flat capillary structure comprises:
a vertical flat main capillary structure formed on an interior surface of the vertical flat cooling main body; and
a vertical flat expansion capillary structure connected to the vertical flat main capillary structure, and formed inside the expansion joint portion.

18. The three-dimensional vapor chamber of claim 17, wherein an end face of the upper shell raising capillary structure is connected to end faces of the vertical flat expansion capillary structure and the expansion joint portion.

19. The three-dimensional vapor chamber of claim 17, wherein the vertical flat expansion capillary structure is engaged with the upper shell raising capillary structure, the vertical flat expansion capillary structure is connected between the upper shell raising capillary structure and the expansion joint portion, or the upper shell raising capillary structure is connected between the vertical flat expansion capillary structure and the raised joint portion.

20. The three-dimensional vapor chamber of claim 17, wherein the upper shell body further comprises:
a joint flange connected to the raised joint portion and engaged with the expansion joint portion of the vertical flat cooling shell, and a part of the vertical flat expansion capillary structure of the vertical flat capillary structure is connected to the upper shell raising capillary structure of the upper shell capillary structure.
